(19) United States
(12) Patent Application Publication
(10) Pub. No.: US 2020/0212418 A1
(43) Pub. Date: Jul. 2, 2020

(54) BATTERY MODULE

(71) Applicant: Contemporary Amperex Technology Co., Limited, Ningde (CN)

(72) Inventors: Shaozhen CHEN, Zhangwan Town (CN); Lilei Su, Zhangwan Town (CN); Chong Wang, Zhangwan Town (CN); Renwei Zheng, Zhangwan Town (CN)

(73) Assignee: Contemporary Amperex Technology Co., Limited, Ningde (CN)

(21) Appl. No.: 16/587,696

(22) Filed: Sep. 30, 2019

(30) Foreign Application Priority Data
Dec. 29, 2018 (CN) 201822246564.X

(51) Int. Cl. H01M 2/34; H01M 10/42; H01M 2/10; H01M 2/22

(52) U.S. Cl. CPC H01M 2/347; H01M 10/425; H01M 2010/4271; H01M 2/22; H01M 2/1022; H01M 2/1077

(57) ABSTRACT

Disclosed herein is a battery module including a plurality of batteries arranged in a length direction, an end plate disposed at an end part of the plurality of batteries in the length direction, a flexible printed circuit (FPC), and a connector. The FPC can include a main body portion located above and electrically connected to a corresponding battery in a height direction, and a bent portion bent and extending from the main body portion and located on the lower side of the main body portion, the bent portion is fixedly connected to the end plate. The connector is fixedly and electrically connected to the bent portion. When the battery module is subjected to vibration shock, the flexible characteristic of the FPC in the present disclosure can be used to transfer and release the shock.

### PRIORITY

This application claims priority to C.N. Application No. CN201822246564.X filed on Dec. 29, 2018, which is incorporated by reference herein.

### FIELD

This disclosure generally relates to the field of batteries, and in particular, to a battery module.

### BACKGROUND

In the design of conventional battery modules, the batteries in the battery module are usually subject to low-voltage sampling by using a flexible printed circuit (FPC). The FPC needs to be connected to an external device by a connector, and the FPC is a soft material per se, so a fixing component needs to be added in the battery module to fix the connector. The typical solution is to add a plastic member for purpose of fixing. However, this can lead to the following disadvantages: the problem about the fixing of the added plastic member exists, basically, the plastic member is fixed above the end plate in the battery module, and may exceed the maximum height of the battery module, and occupy extra space; the connector and the plastic member fixed thereby require a relatively large groove disposed on the end plate, which leads to stress concentration of the end plate, as a result, the expansion resistance of the entire battery module is reduced; and when the connector is subjected to vibration shock, the added plastic member cannot effectively transfer and release the impact applied to the connector.

Therefore, there is a need for a battery module that can effectively transfer and release any impact applied to the connector.

### SUMMARY

Disclosed herein is a battery module including a plurality of batteries arranged in a length direction, an end plate disposed at an end part of the plurality of batteries in the length direction, a flexible printed circuit (FPC), and a connector fixedly connected to the bent portion and electrically connected to the FPC. The FPC can include a main body portion located above a corresponding battery of the plurality of batteries in a height direction and electrically connected to the corresponding battery, and a bent portion located on a lower side of the main body portion and extending from the main body portion, the bent portion fixedly connected to the end plate.

In some embodiments, the battery module can include a connecting plate connected to the end plate and the bent portion.

In some embodiments, the connector and the connecting plate can be respectively located on opposite sides of the bent portion.

In some embodiments, the end plate can be provided with two protrusions protruding upward from a top of the end plate, forming a containing space between the two protrusions. The main body portion and the bent portion can be overlapped in the height direction. The connecting plate can be located between the main body portion and the bent portion in the height direction, and the connecting plate can be fixed to the two protrusions. The connector can be located in the containing space between the two protrusions. The connector can include an inserting port that faces an outside of the battery module in the length direction.

In some embodiments, the battery module can include a first fastener and a second fastener respectively located on both sides of the connector in a width direction, and the connecting plate, the main body portion, the bent portion, and the protrusions of the end plate can be fixed by the first fastener and the second fastener.

In some embodiments, the bent portion can extend downwardly from a top of the end plate along an outer surface of the end plate in the length direction. The connecting plate can be located between the bent portion and the outer surface of the end plate in the length direction, and can be fixed to the outer surface of the end plate in the length direction. The connector can include an inserting port that is disposed in a width direction.

In some embodiments, the connecting plate can include an exposed portion downwardly exceeding a bottom end of the bent portion, and the exposed portion can be located on a lower side of the connector and fixed to the outer surface of the end plate in the length direction.

In some embodiments, the battery module can include a third fastener fixing the exposed portion and the outer surface of the end plate.

In some embodiments, the battery module can include a fourth fastener located on an upper side of the connector, wherein the connecting plate, the outer surface of the end plate and the bent portion can be fixed by the fourth fastener.

In some embodiments, the battery module can include a third fastener and a fourth fastener. The connecting plate can include an exposed portion downwardly exceeding a bottom end of the bent portion. The exposed portion can be located on a lower side of the connector, and can be fixed to the outer surface of the end plate in the length direction by the third fastener. The fourth fastener can be located on the upper side of the connector. The connecting plate, the outer surface of the end plate, and the bent portion can be fixed by the fourth fastener.

In some embodiments, the connecting plate can include an exposed portion exceeding both ends of the bent portion in the width direction, and the exposed portion can be located on both sides of the connector in the width direction and fixed to the outer surface of the end plate in the length direction.

### BRIEF DESCRIPTION OF DRAWINGS

In order to facilitate a full understanding of the present disclosure, reference is now made to the accompanying drawings, in which like elements are referenced with like numerals. These drawings should not be construed as limiting the present disclosure, but are intended to be illustrative only. The drawings are not necessarily to scale, or inclusive of all elements of a system, emphasis instead generally being placed upon illustrating the concepts, structures, and techniques sought to be protected herein.

FIG. 1 is a three-dimensional diagram of a battery module, according to some embodiments of the present disclosure;

FIG. 2 is a three-dimensional diagram of the battery module of FIG. 1 from a different angle, according to some embodiments of the present disclosure;

FIG. 3 an enlarged three-dimensional diagram of circle A in FIG. 2 from a different angle, according to some embodiments of the present disclosure;

FIG. 4 is an exploded three-dimensional diagram of some components in the battery module of FIG. 1, according to some embodiments of the present disclosure;

FIG. 5 is a three-dimensional diagram of a battery module, according to some embodiments of the present disclosure;

FIG. 6 is an enlarged three-dimensional diagram of circle B in FIG. 5 from a different angle, according to some embodiments of the present disclosure;

FIG. 7 is an exploded three-dimensional diagram of some components in the battery module of FIG. 4, according to some embodiments of the present disclosure;

FIG. 8 is a partially enlarged three-dimensional diagram of some the components in the battery module of FIG. 4, according to some embodiments of the present disclosure; and

FIG. 9 is an exploded three-dimensional diagram of some components in the battery module of FIG. 8, according to some embodiments of the present disclosure.

### DESCRIPTION

The battery module according to the present disclosure will be further described in detail with reference to the accompanying drawings.

The elements in the figures are described in the following:

1: battery

2: end plate

21: protrusion

211: top wall

22: outer surface

23: cavity

231: wall

3: FPC

31: main body portion

32: bent portion

4: connector

41: inserting port

5: connecting plate

51: exposed portion

6: electrical connecting piece

G: buckling groove

F1: first fastener

F2: second fastener

F3: third fastener

F4: fourth fastener

S: containing space

L: length direction

W: width direction

H: height direction

The drawings illustrate the embodiments of the present disclosure, it is understood that the disclosed embodiments are only examples of the present disclosure, and the disclosure herein can be implemented in various forms. Therefore, the specific details disclosed herein should be explained only as the basis of claims rather than limiting, and are intended to teach those ordinary skilled in the art to implement the present disclosure in various forms as a representative basis.

Unless otherwise expressly stated and defined, the terms “first,” “second,” “third,” and “fourth” in this application are only used for description, and should not be construed as indicating or implying the relative importance. The term “a plurality of” can mean two or more. The terms “connection” and “fixation” should be construed in a broad sense. For example, “connection” can be fixed connection, removable connection, integral connection, or electrical connection; also, it can be direct connection or indirect connection through an intermediary. For those skilled in the art, the specific meanings of the above terms in the present application can be understood on a case-by-case basis.

In the present disclosure, the direction indicated by arrow L in all the drawings can mean the length direction, the direction indicated by arrow W can mean the width direction, and the direction indicated by arrow H can mean the height or vertical direction. The horizontal direction can mean the direction parallel to the horizontal plane, can be said length or width direction. In addition, the horizontal direction can include not only the direction absolutely parallel to the horizontal plane but also the direction generally parallel to the horizontal plane according to conventional engineering cognition. The height or vertical direction can mean the direction perpendicular to the horizontal plane, and can include not only the direction absolutely perpendicular to the horizontal plane but also the direction generally perpendicular to the horizontal plane according to conventional engineering cognition. Moreover, “upper”, “lower”, “top”, “bottom” and the like described in this disclosure can be expressed relative to the height direction. For the convenience of understanding and explanation, the directions will be described hereinafter based on the L-W-H coordinate system in the drawings.

The type of battery in the present disclosure can include, but is not limited to, lithium ion battery, aluminum ion battery, carbon battery, flow battery, lead-acid battery, glass battery, magnesium ion battery, metal air battery, molten salt battery, nickel cadmium battery, nickel hydrogen battery, nickel iron battery, nickel metal hydride battery, nickel zinc battery, organic radical battery, polymer-based battery, fuel cell, lithium sulfur battery, sodium ion battery, sodium sulfur battery, and zinc ion battery. In some embodiments, the battery can be a lithium ion battery.

In the battery module according to the present disclosure, the connector can be fixedly connected to the bent portion of the flexible printed circuit (FPC), and the bent portion can be fixedly connected to the end plate. Therefore, the connector is fixed to the end plate by the FPC. When the connector is subjected to vibration shock, the flexible characteristic of the FPC can be used to transfer and release the shock.

The battery module according to the present disclosure can include a plurality of batteries 1 arranged in a length direction L, an end plate 2 disposed at an end part of the plurality of batteries 1 in the length direction L, a flexible printed circuit (FPC) 3, and a connector 4. FPC 3 can include a main body portion 31 and a bent portion 32, main body portion 31 can be located above a corresponding battery 1 in a height direction H and can be electrically connected to the corresponding battery 1, bent portion 32 can be bent and extend from main body portion 31 and can be located on the lower side of main body portion 31. Bent portion 32 can also be fixedly connected to end plate 2. Connector 4 can be fixedly connected to bent portion 32 of FPC 3 and electrically connected to FPC 3. The battery module can further include a connecting plate 5 connected to end plate 2 and bent portion 32 of FPC 3. FPC 3 can be a flexible board, and connecting plate 5 can play a role of strengthening the hardness of FPC 3 and complementing the thickness of FPC 3. Exemplary material of connecting plate 5 can include, but not limited to plastic and other insulating materials.

Battery 1 can be a hard-shell battery (or referred to as a can-type battery) or a soft-pack battery (or referred to as a bag-type battery), and the hard-shell battery can include an electrode component (not shown), a pole, an explosion-proof valve, a housing, and a top cover. A containing cavity is formed inside the housing to accommodate the electrode component and electrolyte. The electrode component can include a positive electrode plate, a negative electrode plate, and a separator separating the positive electrode plate from the negative electrode plate. The electrode component can be formed by winding the positive electrode plate, the negative electrode plate, and the separator, or laminating the positive electrode plate, the negative electrode plate, and the separator. Each of the positive electrode plate and the negative electrode plate can include a current collector and an active material layer disposed on the current collector. The soft-pack battery can include a package bag as a battery case (for example, formed by an aluminum plastic film), an electrode component (similar to the formation and molding of the hard-shell battery), and a tab. A part of the tab can be packaged within the package bag and the other part can extend out of the package bag. The tab can be formed directly by an electrode plate or can adopt a separate conductive material and can be electrically connected to the current collector.

Bent portion 32 of FPC 3 can be fixedly connected to end plate 2 in multiple fixing manners. In some embodiments, bent portion 32 of FPC 3 can be fixedly connected to outer surface 22 of end plate 2. In some embodiments, bent portion 32 of FPC 3 can be fixedly connected to the top of end plate 2.

The fixed connection between bent portion 32 of FPC 3 and outer surface 22 of end plate 2 according to some embodiments of the present disclosure is further discussed below.

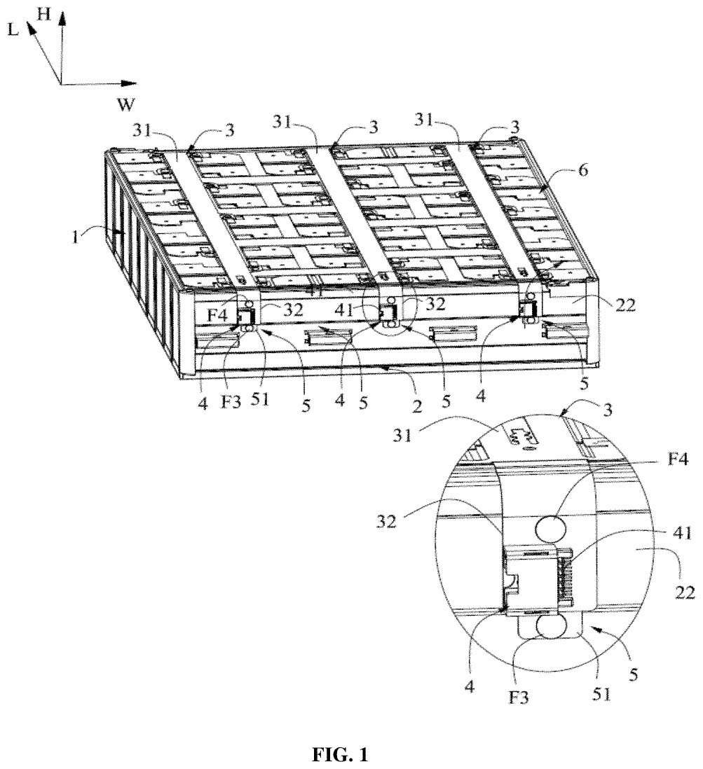

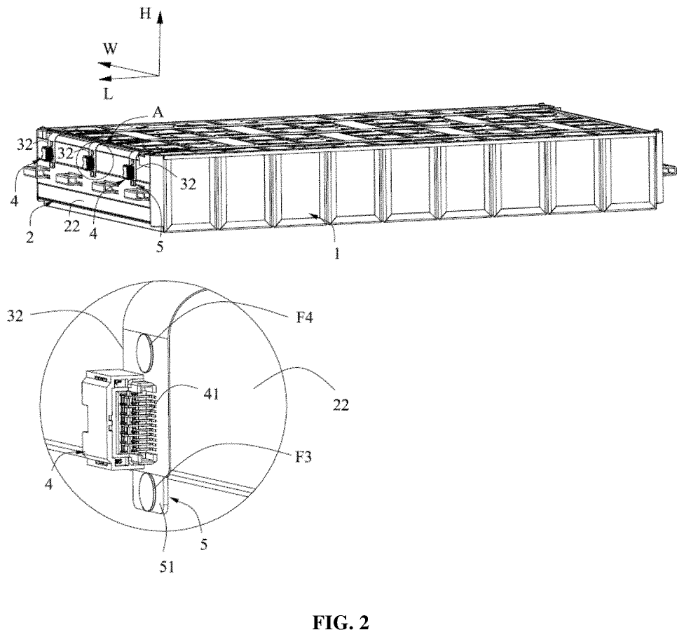

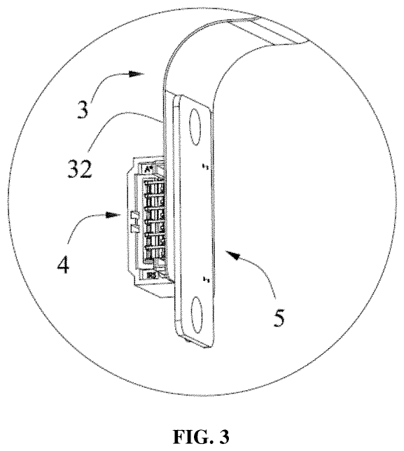

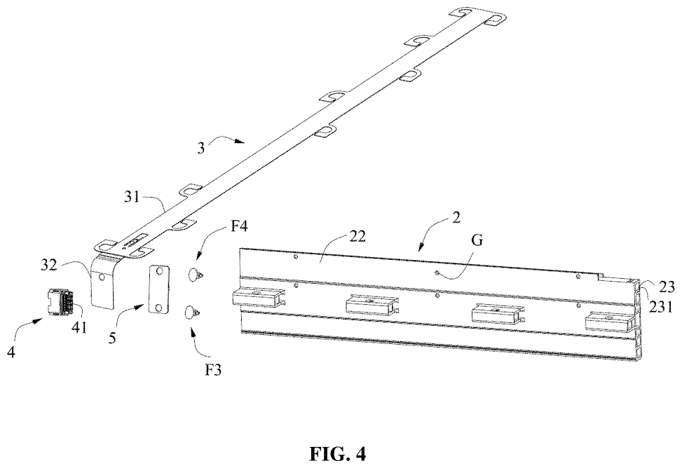

FIG. 1 is a three-dimensional diagram of a battery module, according to some embodiments of the present disclosure. FIG. 2 is a three-dimensional diagram of the battery module of FIG. 1 from a different angle, according to some embodiments of the present disclosure. FIG. 3 is an enlarged three-dimensional diagram of circle A in FIG. 2 from a different angle, according to some embodiments of the present disclosure. FIG. 4 is an exploded three-dimensional diagram of some components in the battery module of FIG. 1, according to some embodiments of the present disclosure.

In FIGS. 1 to 4, bent portion 32 of FPC 3 can extend downward from the top of end plate 2 along outer surface 22 of end plate 2 in the length direction L. Connecting plate 5 can be located between bent portion 32 of FPC 3 and outer surface 22 of end plate 2 in the length direction L, and is fixed to outer surface 22 of end plate 2 in the length direction L. An inserting port 41 of connector 4 can be disposed in the width direction W to save space.

Referring to FIGS. 1 to 4, connecting plate 5 can be connected to bent portion 32 of FPC 3 and can be fixedly connected to outer surface 22 of end plate 2 in the length direction L. FPC 3 is a flexible board, and connecting plate 5 can be bonded to bent portion 32 of FPC 3. Bent portion 32 of FPC 3 and outer surface 22 of end plate 2 can be fixed by connecting plate 5 in multiple manners. In some embodiments, connecting plate 5 can include an exposed portion 51 exceeding bent portion 32 of FPC 3, and connecting plate 5 and outer surface 22 of end plate 2 can be fixed by exposed portion 51 of connecting plate 5 so as to indirectly fix bent portion 32 of FPC 3 and outer surface 22 of end plate 2.

In some embodiments, connecting plate 5 can include exposed portion 51 downwardly exceeding the bottom end of bent portion 32 of FPC 3, exposed portion 51 can be located on the lower side of connector 4 and fixed to outer surface 22 of end plate 2 in the length direction L, such that bent portion 32 of FPC 3 and end plate 2 can be indirectly fixed by exposed portion 51 of connecting plate 5. The battery module can further include a third fastener F3, and exposed portion 51 and outer surface 22 of end plate 2 can be fixed by third fastener F3.

In some embodiments, connecting plate 5 can include exposed portion 51 of connecting plate 5 exceeding from both ends of bent portion 32 in the width direction W, and exposed portion 51 can be located on both sides of connector 4 in the width direction W, and can be fixed to the outer surface 22 of end plate 2, such that bent portion 32 of FPC 3 and end plate 2 can be indirectly fixed by exposed portion 51 of connecting plate 5. Exposed portion 51 located on both sides of connector 4 in the width direction W and outer surface 22 of the end plate 2 can also be fixed by third fastener F3.

In some embodiments, connecting plate 5, outer surface 22 of end plate 2, and bent portion 32 of FPC 3 are fixed together. In some embodiments, the battery module can further include a fourth fastener F4 located on the upper side of connector 4, and connecting plate 5, outer surface 22 of end plate 2, and bent portion 32 of FPC 3 can be fixed together by fourth fastener F4.

In some embodiments, connecting plate 5 and outer surface 22 of end plate 2 are fixed by exposed portion 51 of connecting plate 5 and connecting plate 5, outer surface 22 of end plate 2 and bent portion 32 of FPC 3 are fixed together.

That is, connecting plate 5 and outer surface 22 of end plate 2 are fixedly connected by exposed portion 51 of connecting plate 5 which can downwardly exceed the bottom end of bent portion 32 of FPC 3, and connecting plate 5, outer surface 22 of end plate 2 and bent portion 32 of FPC 3 are fixedly connected together. As shown in FIGS. 1 to 4, the battery module can include third fastener F3 and fourth fastener F4. Connecting plate 5 can include exposed portion 51 which can downwardly exceed the bottom end of bent portion 32 of FPC 3, exposed portion 51 can be located on the lower side of connector 4, and is fixed to the outer surface 22 of the end plate 2 in the length direction L by the third fastener F3. The fourth fastener F4 is located on the upper side of the connector 4, and connecting plate 5, outer surface 22 of end plate 2 and bent portion 32 of FPC 3 can be fixed together by fourth fastener F4.

In some embodiments, third fastener F3 and fourth fastener F4 can be buckling nails, which can occupy a small space and can be firmly connected. Correspondingly, a cavity 23 can be formed in end plate 2, and a wall 231 of cavity 23 can be provided with a buckling groove G, and the buckling nails can be buckled in the buckling groove G. End plate 2 provided with cavity 23 therein can also reduce the weight of the battery module. The fixing manner in which bent portion 32 of FPC 3 and outer surface 22 of end plate 2 are fixed by connecting plate 5 can be selected according to specific needs.

Bent portion 32 of FPC 3 can be fixedly connected to outer surface 22 of end plate 2, an additional plastic member fixing connector is not required to be added, the extra space in the height direction of the battery module is not occupied, and the end plate is not required to be grooved to avoid stress concentration of the end plate. Moreover, when connector 4 is subject to vibration shock, the flexible characteristic of FPC 3 can be used to transmit and release the shock to ensure the service life of the battery module.

The fixed connection between bent portion 32 of FPC 3 to the top of end plate 2 according to some embodiments of the present disclosure is further discussed below.

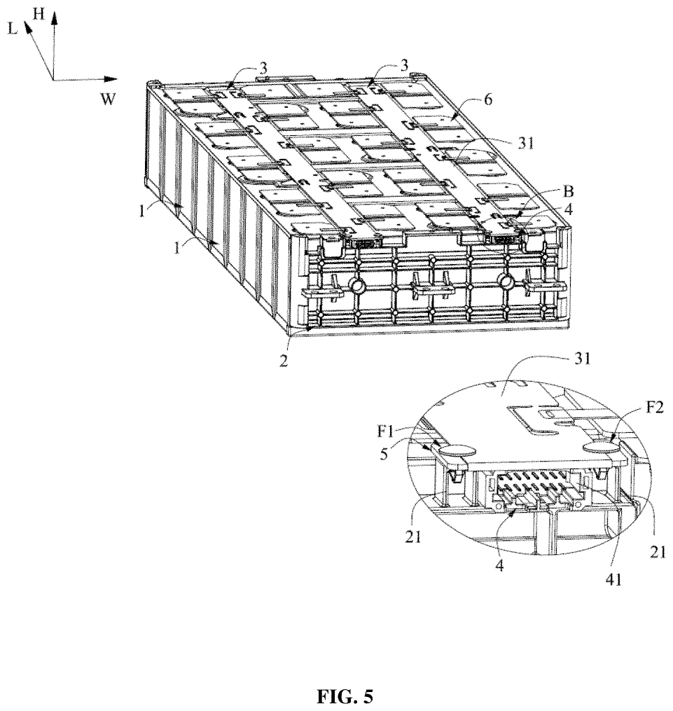

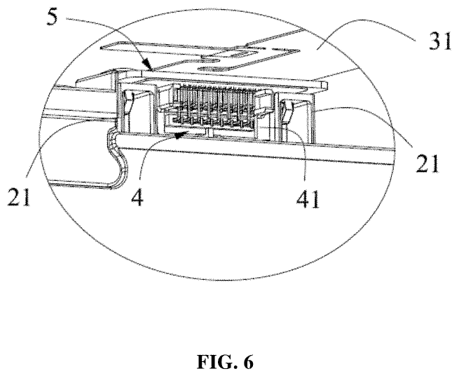

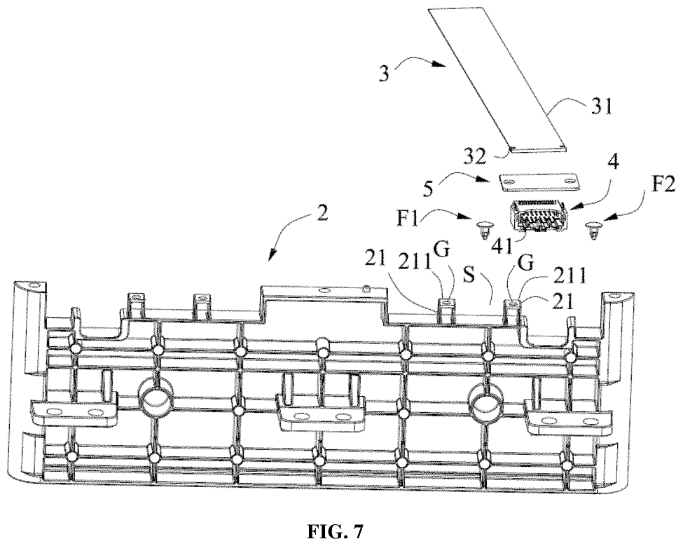

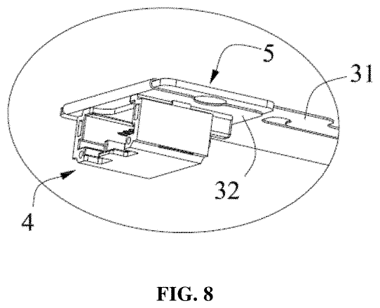

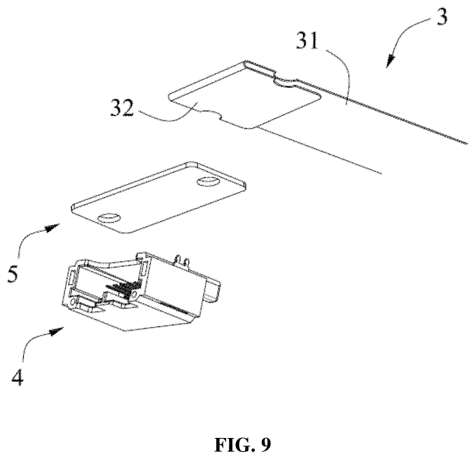

FIG. 5 is a three-dimensional diagram of a battery module, according to some embodiments of the present disclosure. FIG. 6 is an enlarged three-dimensional diagram of circle B in FIG. 5 from a different angle, according to some embodiments of the present disclosure. FIG. 7 is an exploded three-dimensional diagram of some components in the battery module of FIG. 4, according to some embodiments of the present disclosure. FIG. 8 is a partially enlarged three-dimensional diagram of some components in the battery module of FIG. 4, according to some embodiments of the present disclosure. FIG. 9 is an exploded three-dimensional diagram of some components in the battery module of FIG. 8, according to some embodiments of the present disclosure.

In FIGS. 5 to 9, end plate 2 can be provided with two projections 21 protruding upward from the top of end plate 2, and a containing space S can be formed between two projections 21. Main body portion 31 and bent portion 32 of FPC 3 can be overlapped in the height direction H, and connecting plate 5 can be located between main body portion 31 and bent portion 32 of FPC 3 in the height direction H. Connecting plate 5 can be fixed to the two protrusions 21, and connector 4 can be located in the receiving space S. Inserting port 41 of connector 4 can face the outside of the battery module in the length direction L, such that connector 4 does not occupy an extra height space of the battery module. The battery module can further include a first fastener F1 and a second fastener F2 which can be respectively located on both sides of the connector 4 in the width direction W. Connecting plate 5, main body portion 31 of FPC 3, bent portion 32 of FPC 3 and projections 21 of end plate 2 can be fixed by first fastener F1 and second fastener F2. First fastener F1 and second fastener F2 can be buckling nails, and protrusions 21 of end plate 2 can be hollow inside. Top walls 211 of protrusions 21 can be provided with buckling grooves G, and the buckling nails can be buckled in buckling grooves G to be fixed. Connecting plate 5 can be bonded to bent portion 32 and main body portion 31 of FPC 3. Connector 4 fixedly connected to bent portion 32 of FPC 3 can be contained by two protrusions 21 protruding upward on the top of end plate 2, and an additional plastic member fixing connector is not required to be added. Main body portion 31 and bent portion 32 of FPC 3 can be overlapped in the height direction H to reduce the influence of FPC 3 on the height of the battery module. The flexibility of FPC 3 can be fully used to transmit and release the shock caused by a vibration working condition.

In some embodiments, connector 4 and connecting plate 5 can be respectively located on opposite sides of bent portion 32 of FPC 3. Connector 4 can be connected to FPC 3 electrically by soldering specifically, and the part where connector 4 and FPC 3 are soldered can be covered with glue to protect the soldering position from being affected and separated by vibration during usage.

Connecting plate 5 can be selectively set as needed. For example, connecting plate 5 can be eliminated, and FPC 3 can be directly fixed by appropriately increasing the strength of FPC 3 per se while the requirement on the flexibility can be met. That is, the strength requirement of connecting and fixing is met.

In the battery module according to some embodiments of the present disclosure, connector 4 can be fixedly connected to bent portion 32 of FPC 3, and bent portion 32 can be fixedly connected to end plate 2. Therefore, connector 4 can be fixed to end plate 2 by FPC 3. When connector 4 is subject to vibration shock, the flexible characteristic of FPC 3 can be used to transmit and release the shock.

The above detailed description describes various exemplary embodiments, but is not intended to be limited to the specifically disclosed combinations. Accordingly, unless stated otherwise, the various features disclosed herein can be combined together to form multiple additional combinations that are not shown for the sake of clarity.

The foregoing are only some embodiments of the present application, and is not intended to limit the present application, and various changes and modifications can be made to the present application for those skilled in the art. Any modifications, equivalent substitutions, improvements, etc., made within the spirit and principles of the present application should be within the scope of the present application.

It should be noted that, although the above embodiments have been described herein, the scope of present disclosure is not limited thereby. Therefore, based on the innovative concept of the present disclosure, modifications to the embodiments described herein, equivalent structural or process transformations based on the contents of the description and drawings of the present disclosure, and direct or indirect application of the above-described technical solutions in other related technical fields are included in the present disclosure.

While the disclosure has been described in connection with certain embodiments, it is to be understood that the disclosure is not to be limited to the disclosed embodiments but, on the contrary, is intended to cover various modifications and equivalent arrangements included within the spirit and scope of the disclosure, which scope is to be accorded the broadest interpretation so as to encompass all such modifications and equivalent structures as is permitted under the law.

What is claimed is:

1. A battery module, comprising:
a plurality of batteries arranged in a length direction;
an end plate disposed at an end part of the plurality of batteries in the length direction;
a flexible printed circuit (FPC) comprising:
a main body portion located above a corresponding battery of the plurality of batteries in a height direction and electrically connected to the corresponding battery; and
a bent portion located on a lower side of the main body portion and extending from the main body portion, the bent portion fixedly connected to the end plate; and
a connector fixedly connected to the bent portion and electrically connected to the FPC.

2. The battery module according to claim 1, comprising a connecting plate connected to the end plate and the bent portion.

3. The battery module according to claim 2, wherein the connector and the connecting plate are respectively located on opposite sides of the bent portion.

4. The battery module according to claim 2, wherein
the end plate is provided with two protrusions protruding upward from a top of the end plate, forming a containing space between the two protrusions;
the main body portion and the bent portion are overlapped in the height direction;
the connecting plate is located between the main body portion and the bent portion in the height direction, and the connecting plate is fixed to the two protrusions; and
the connector is located in the containing space between the two protrusions, and;
the connector includes an inserting port that faces an outside of the battery module in the length direction.

5. The battery module according to claim 4, comprising a first fastener and a second fastener respectively located on both sides of the connector in a width direction, and the connecting plate, the main body portion, the bent portion, and the protrusions of the end plate are fixed by the first fastener and the second fastener.

6. The battery module according to claim 2, wherein
the bent portion extends downwardly from a top of the end plate along an outer surface of the end plate in the length direction;
the connecting plate is located between the bent portion and the outer surface of the end plate in the length direction, and is fixed to the outer surface of the end plate in the length direction; and
the connector includes an inserting port that is disposed in a width direction.

7. The battery module according to claim 6, wherein the connecting plate comprises an exposed portion downwardly exceeding a bottom end of the bent portion, and the exposed portion is located on a lower side of the connector and is fixed to the outer surface of the end plate in the length direction.

8. The battery module according to claim 7, comprising a third fastener fixing the exposed portion and the outer surface of the end plate.

9. The battery module according to claim 6, comprising a fourth fastener located on an upper side of the connector, wherein the connecting plate, the outer surface of the end plate and the bent portion are fixed by the fourth fastener.

10. The battery module according to claim 6, comprising a third fastener and a fourth fastener, wherein:
the connecting plate comprises an exposed portion downwardly exceeding a bottom end of the bent portion,
the exposed portion is located on a lower side of the connector, and is fixed to the outer surface of the end plate in the length direction by the third fastener,
the fourth fastener is located on an upper side of the connector, and
the connecting plate, the outer surface of the end plate, and the bent portion are fixed by the fourth fastener.

11. The battery module according to claim 6, wherein the connecting plate comprises an exposed portion exceeding both ends of the bent portion in the width direction, and the exposed portion is located on both sides of the connector in the width direction and is fixed to the outer surface of the end plate in the length direction.
